(19) United States
(12) Patent Application Publication
(10) Pub. No.: US 2022/0352715 A1
(43) Pub. Date: Nov. 3, 2022

(54) MONITORING INSTALLATION AND MONITORING SYSTEM FOR MONITORING AND/OR CONTROLLING AT LEAST ONE ELECTRICAL PARAMETER IN AN ELECTRICAL SUPPLY SYSTEM, AND COMPUTER PROGRAMME

(71) Applicant: TESVOLT GmbH, Lutherstadt Wittenberg (DE)

(72) Inventor: Simon Schandert, Lutherstadt Wittenberg (DE)

(73) Assignee: TESVOLT GmbH, Lutherstadt Wittenberg (DE)

(21) Appl. No.: 17/731,741

(22) Filed: Apr. 28, 2022

(30) Foreign Application Priority Data
Apr. 30, 2021 (DE) 202021102361.9

(51) Int. Cl. H02J 3/00; H02J 3/46; H02J 3/14; H02J 3/32; H02J 13/00

(52) U.S. Cl. CPC H02J 3/0075; H02J 3/004; H02J 3/466; H02J 3/144; H02J 3/32; H02J 13/00004; H02J 2203/10

(57) ABSTRACT

Described herein is a monitoring installation and a monitoring system for monitoring and/or controlling at least one electrical parameter in an electrical supply system, as well as to an associated computer program.

### CROSS-REFERENCE TO RELATED APPLICATIONS

This application claims priority to German Patent Application No. 202021102361.9, filed on Apr. 30, 2021, the contents of which are incorporated by reference herein in their entirety.

### FIELD

The present invention relates to a monitoring installation and a monitoring system for monitoring and/or controlling at least one electrical parameter in an electrical supply system, as well as to an associated computer program.

### BACKGROUND

Particularly in complex electrical supply systems, there is a requirement to optimise individual parameters and/or to determine costs incurred as well as available capacities.

Therefore, it is necessary to measure electrical parameters and to make their measured values available. Depending on the spatial extent of the electrical system in question or also depending on the distance of a user from the electrical system, such a determination of electrical parameters can be difficult for the user.

Internet-based solutions for monitoring and controlling remote devices or systems offer far-reaching advantages here.

DE102012200714A1 relates, for example, to a method for data communication between a domestic appliance on the one hand and a user terminal of a user of the domestic appliance on the other hand, wherein in the context of the data communication control data with control commands are transmitted to the domestic appliance and/or status data with information about a current state of the domestic appliance are transmitted from the domestic appliance to the user terminal, wherein the data communication between the domestic appliance and the user terminal is carried out at least sections-wise via the internet by means of an internet server.

DE202015001512U1 discloses a system for remote control of an electrical installation, comprising a first and a second computing unit, wherein the second computing unit is to be remotely controlled. A first optical display installation is connected to the second computing unit. It is provided that a remote control unit is connectable to the system for communication with installations to be remotely controlled. The system and the remote control installation are connected via the internet.

Although it is possible with known solutions to determine electrical parameters on modules that consume electrical energy, such solutions do not yet enable the user to determine and evaluate or control electrical parameters on one or more electrical supply systems.

In addition, there is the requirement that the public electricity grid should be protected from overloads caused by the feed-in of large regenerative plants. Depending on the capacity of the local grid infrastructure, plants of certain performance classes may therefore not be installed unless it is ensured that the generating plant can never feed into the grid.

### SUMMARY

The objective of the invention is therefore to provide a monitoring installation as well as a monitoring system with which electrical parameters of electrical supply systems can be read-out and/or controlled in a simple as well as efficient and essentially location-independent manner.

This objective is solved by the monitoring installation according to claim 1 and by the monitoring system according to claim 6. Advantageous embodiments of the monitoring installation are given in subclaims 2-5. An advantageous embodiment of the monitoring system is given in subclaim 7.

Additionally, a computer program according to claims 8-10 is provided.

The features of the claims may be combined in any technically useful manner, wherein the explanations from the following description as well as features from the figures may also be incorporated, which comprise complementary embodiments of the invention.

A first aspect of the present invention is a monitoring installation for monitoring and/or controlling at least one electrical parameter in an electrical supply system, comprising at least one port, such as an electrical and/or control port, at the electrical supply system as well as a measuring installation for measuring at least one electrical parameter at the port. Furthermore, the monitoring installation comprises an internet interface for transmission of at least one information, such as a numerical value, regarding the electrical parameter to a user terminal via the internet and/or for transmission of at least one control command entered into a user terminal for controlling at least one electrical parameter in the electrical supply system via the internet.

The measuring installation can be understood as any detection installation.

The user terminal is particularly equipped with a screen for the optical output of the numerical value.

In this context, the monitoring installation can comprise an electrical battery storage as an electrical supply system, wherein the measuring installation is connected to a port of the battery storage.

In particular, the electrical battery storage is an electrochemical battery comprising several cell modules.

Furthermore, the monitoring installation can comprise a photovoltaic system as an electrical supply system, wherein the measuring installation is connected to a port of the photovoltaic system.

A further alternative embodiment provides that the monitoring installation comprises a port on an external energy supply grid, wherein the measuring installation is connected to the port at the external energy supply grid.

The measured electrical parameter can be:
the voltage present at the port
the electric current present at the port
the electrical charge present in the electrical supply system, in particular in the configuration in which the electrical supply system is a battery storage.

A further aspect of the present invention is a monitoring system for monitoring and/or controlling at least one electrical parameter in an electrical supply system, comprising at least one monitoring installation according to the invention as well as an internet server and a user terminal, via which at least one information and/or control command relating to the electrical parameter can be transmitted with a data communication via the internet between the internet interface and a user terminal.

Accordingly, it is provided that the monitoring system is configured to read out and transmit at least one value of an electrical parameter and/or to transmit a control command via the internet to influence at least one electrical parameter in the electrical supply system.

In particular, this transmission and display of electrical parameters can take place in real time.

The monitoring system can comprise a consumer and be configured to transmit via the internet between the internet interface and the user terminal at least information relating to an electrical parameter realized in the consumer and/or to transmit a control command for setting an electrical parameter to be realized in the consumer.

Here, too, it is provided that the user terminal is configured to display the electrical parameter determined in the consumer or generator or to generate and display the control command.

Thus, the user terminal or the entire monitoring system can be configured to control or read out a charging station, such as a charging station for an electrically powered vehicle. In particular, the so-called state of charge of individual modules of a connected battery storage unit, in particular of a battery storage unit of an electric vehicle, can also be balanced.

Another aspect of the present invention is a computer program, in particular an app, which can be loaded into the internal, in particular non-volatile, memory of a digital computer and which comprises computer program code which, when executed on the digital computer, transmits via the internet protocol:
an information relating to the electrical parameter determined by means of the monitoring system according to the invention to the user terminal, and/or
a control command entered by means of the user terminal of the monitoring system according to the invention to the electrical supply system for controlling at least one electrical parameter.

The computer program can be configured to initiate a graphical display on a user interface of the user terminal.

The computer programme is configured to execute data communication via the internet.

In other words, the computer program realises a website for displaying and/or controlling at least one measured electrical parameter.

For the purpose of explaining the website and in the context of the present invention, unless explicitly used otherwise, the term “user” refers to an operator, installer, end customer, professional partner, service employee, in particular a person using a monitoring installation, a monitoring system and/or a computer program according to the invention.

The term “external energy supply grid” refers to a public electricity grid.

The term “consumer” refers to at least one electrically operated and/or operable device and/or apparatus integrated into the monitoring system according to the invention.

The term “micro-grid” refers to a small electrical supply system with or without direct connection to an external energy supply grid, wherein at least one decentralised energy supply system and/or an electrical battery storage at least partially cover the energy demand.

The term “off-grid” refers to an electrical supply system without a direct link to an external energy supply grid, in which a decentralised energy supply system covers the entire energy demand.

The term “peninsula” refers to an electrical supply system in which consumers are either supplied only from the grid or 100% from storage and generators on the non-grid side.

The term “component” and/or “components” refers to one or more electrically operated and/or operable devices and/or installations connected to the electrical supply system for power generation, power feed-in and/or power consumption.

The term “electrical parameter” refers to a physical quantity and/or a parameter derived from it.

In an embodiment, a user interface, in particular a website, is initiated by initiating a computer program, in particular an app, which is configured to receive measured data from a measuring installation of a monitoring installation via an internet server for control and to display it graphically and/or also to send data within a monitoring system to the monitoring installation for controlling electrical parameters in the electrical supply system.

In an embodiment, a website is configured to graphically display to a user information about at least one current status of at least one energy flow derived from at least one electrical parameter measured by the measuring installation of the monitoring installation. In particular, this website is configured to update and graphically display the totality of the electrical parameters measured by the measuring installation essentially in real time, respective to the change of the electrical parameters. Thereby, each component integrated in an electrical supply system and connected to the monitoring installation via a port is graphically displayed as an icon. Furthermore, the at least one electrical parameter of the respective component is provided to a user next to the respective icon. In addition, the energy flows are derived on the basis of the measured electrical parameter for a respective component of the electrical supply system and displayed graphically in order to display to a user the entirety of the energy flows and thus the current status of the electrical supply system in a clear manner. The components in the electrical supply system connected via a port to the monitoring installation are arranged in a circle in this graphical display. Arrows indicate the respective energy flow of a component of the electrical supply system, respectively, for example when energy stored in an electrical battery is required for self-consumption and/or charging and/or operating other components connected in the electrical supply system. In this case, the graphical display of the website is automatically updated to the user, respective to the measured electrical parameters, to make it accordingly recognisable in real time which component of the electrical supply system contributes how much to energy generation and/or consumption. For example, a user can be graphically displayed a state of charge of an electric battery or an electrically powered vehicle as well as the energy consumption of a heat pump or other components in the electric supply system.

The graphical display described here is additionally configured to graphically display the energy flows measured by the measuring installation in real time and their electrical parameters essentially in real time as well, and to update the graphical display accordingly. Furthermore, the respective components as well as battery storage and photovoltaic system, which are represented by icons in the graphical display, can be clicked on individually to display a more detailed representation of the electrical parameters.

Additionally, the portion of the electrical supply system that is in self-sufficiency is graphically displayed to the user based on the data transmitted by the monitoring installation. In other words, for example, what percentage of the current energy demand is obtained from self-generated energy, such as from a photovoltaic system or energy from an electrochemical battery storage, and how much of the total energy is obtained from the external energy supply grid to cover the rest of the energy demand.

Wherever the legal framework conditions allow decentrally generated energy to be fed into an external energy supply grid, it can be advantageous to feed surplus decentrally generated energy, such as from a photovoltaic system, into the external energy supply grid, not only to realise economic advantages through a so-called direct marketer interface, but also, if necessary, to contribute to short-term grid stabilisation (primary control power PRL, secondary control power SRL, minute reserve power MRL). Furthermore, it can be advantageous to operate an electrical supply system as a micro or, if necessary, off-grid system in order to ensure an energy supply that is as independent as possible from an external energy supply grid.

Where a direct feed-in of decentrally generated energy into an external energy supply grid is not feasible, a so-called peninsula operation can significantly optimise the energy self-consumption. It is also conceivable that in the event of a failure of the external energy supply grid, the energy supply can be switched to a substitute power supply by a decentralised energy supply system.

Accordingly, the website described further above is also configured to graphically display to the user the portion of decentrally generated and/or stored energy required for self-supply of the electrical supply system and, respectively, the portion of excess decentrally generated and/or stored energy that can be made available for storage or, as the case may be, feed-in to an external energy supply grid.

Furthermore, the website is configured to click on the respective components, displayed as icons, which are integrated in the electrical supply system, in order to be forwarded to a further embodiment of the website, which is configured to graphically display a detailed overview of the measured electrical parameters of the respective component and those derived from the measured value to the user. In other words, the user is provided with a measured value analysis of measured electrical parameters of the components integrated in the electrical supply system.

Furthermore, this website is configured to graphically display the electrical parameters measured by a monitoring installation over a time period, in particular a time period of the last 24 hours, in particular the last 7 days, in particular the last 30 days, in particular the last 12 months, in particular any day from the time of installation of the monitoring installation according to the invention, or the entire time period from the time of installation of the monitoring installation according to the invention.

In a possible embodiment, the display of the measured electrical parameters is unlimited in time, i.e. possibly also for years in the past.

For example, although not limiting, the electrical energy fed into the electrical supply system by a photovoltaic system can be displayed to a user within the time periods described above.

Furthermore, the electrical energy stored by an electrical battery storage and/or fed into the electrical supply system can be displayed within the time periods described above.

All measured electrical parameters of all components can also be displayed respective to their energy flow within the time periods described above. In addition, the website is configured to provide the aforementioned display of electrical parameters for individual components as well. For example, the state of charge of a battery or an electrically powered vehicle or the temperature of a heat pump can be displayed within the time periods described above. In some embodiments of this website, individual measured values can be read out from the totality of the displayed measured values by mouse-over events, or the totality of the measured values of the selected components and/or energy flows in a selected time period, as described above, can be exported and made available for further measured value analysis.

In a further embodiment, a website is configured to graphically display to a user an energy balance of the components integrated in an electrical supply system. Thereby, the user can essentially inspect the energy consumption of the respective components of the electrical supply system connected to the monitoring installation, such as the consumption of electrical energy, e.g. how much energy was obtained from an external energy supply grid, was fed-in directly to the electrical supply system from a photovoltaic system, was fed-in to the electrical supply system from an electrical battery storage, was fed-in to a heat pump, an electrically operated vehicle and/or other consumers in the electrical supply system.

In a further embodiment, a website is configured to display to a user a graphical display of the measured values of the decentrally generated and/or stored energy of the components in the electrical supply system. Thereby, the graphical display can, for example, display the electrical energy that has been provided by a photovoltaic system and/or stored by an electrical battery storage system, as well as a measured value of surplus energy that is provided for feed-in to an external energy supply grid.

In a further embodiment, a website is configured to display a combined summary display of energy consumption and energy generation that highlights to a user an energy balance of the energy consumption and energy generation of the components of an electrical supply system connected to a monitoring system.

A respective energy report is downloadable

In a further embodiment of a website, a graphical display of at least one electrical parameter for the generation of electrical energy, for example by a photovoltaic system, is provided to a user based on weather forecasts. In this case, a forecast of the electrical energy to be generated in the future by the energy-generating components in the electrical supply system is provided to the user on the basis of weather forecast data and at least partially overlaid with the actually measured measured values provided by a monitoring system via data communication with an internet server. In a further embodiment of this website, the forecast can also take place on the basis of the expected radiation and/or global radiation. In a further embodiment of this website, the forecast is provided to the user based on weather data, such as temperature data in combination or individually with precipitation values. In a further embodiment of a website, at least a forecast of an electrical energy to be generated in the future, for example by a photovoltaic system, as well as a value of a maximum power of said photovoltaic system can be entered by the user in a mask in order to ensure optimal use and energy yield of a decentralised energy supply system.

In a further embodiment of a website, yields from a decentralised energy supply system are graphically displayed to a user. The data of a forecast described above can be overlaid with the actual measured values provided by the measuring installation in the monitoring system in order to provide the user with an overview of the decentrally generated energy yields on a monthly and/or yearly basis. In this embodiment, energy yields of several years can also be superimposed in order to provide the user with information about possible changes. Furthermore, in this embodiment, average values of at least one electrical parameter are also displayed on a monthly basis to enable the user to make changes to the energy consumption based on the data or to optimise the energy consumption by means of forecast-based charging.

All measured values shown in graphical displays, which provide information about measured values measured by the measuring installation of the components of an electrical supply system integrated in a monitoring system, can be read out individually by mouse-over events or exported together with other measured values, respective to the graphical display, for further data analysis.

In a further embodiment of a website, at least one information about a meter reading of at least one component of an electrical supply system integrated in a monitoring installation is graphically displayed to a user. In particular, a monthly overview of all meter readings of all components of the electrical supply system integrated in the monitoring installation is graphically displayed.

In a further embodiment of a website, a graphical display of a State of Charge (SoC) of at least one at least partially electrically operated/rechargeable vehicle is displayed to a user. The user is provided with at least one setting option for a configuration of the SoC-controlled charging.

Thus, the user can create and/or upload at least one charging profile for the at least one at least partially electrically operated vehicle based on a forecast of a stored and/or expected energy to be generated, so that the at least partially electrically operated vehicle is optimally charged. Furthermore, the user can also make settings that guarantee the fastest possible charging of the at least partially electrically operated vehicle.

Thereby, an intelligent networking of at least one charging station for an at least partially electrically operated vehicle is provided.

In some embodiments, the computer program, in particular an app, may be running on a user terminal, for example, but not limiting to, a personal computer, PC, desktop computer or even portable terminals, such as mobile phones, tablet PCs or laptops, provided that an internet interface is available.

In some embodiments, the computer program may in particular be an app running as a web-based app on a user terminal.

Whenever abbreviations or strange technical terms appear, perhaps additional, comprehensible information can be taken from this overview and included in the application text:

Furthermore, the computer program can be configured to initiate a measurement of the electrical parameter. The user terminal can be configured respectively to be a transmitter as well as a receiver of data for evaluating the electrical parameter or for controlling the electrical parameter. The same applies to the port on the electrical supply system, which can also be designed as a transmitter and/or receiver.

The invention therefore relates to an energy management system which is capable of controlling and/or displaying energy functions via the Internet.

It forms a so-called peninsula solution.

Thus, the present invention offers an alternative to a cost-intensive grid expansion or enables the arbitrary power expansion of renewable energies, even in situations where a feed-in into a regional public grid is not possible or not permitted.

The invention can technically realise a one-sided island grid by enabling electrical energy to be obtained from a public grid while preventing electrical energy from being fed-in to the grid.

It also offers a supplementary solution when a grid connection cannot supply the amount of energy required.

This makes it possible to control decentralised energy supply systems in such a way that no feed-in or a so-called 0 feed-in takes place into the public energy grid.

In particular, the invention can be designed in such a way that the energy input into the public grid is reduced to 90% within less than 20 ms, and the energy input into the public grid is completely reduced within 10 seconds.

In this way, an imminent grid overload can be prevented.

The peninsula solution ensures that, for example, a photovoltaic system can be connected to a decentralised energy supply grid and provides electrical energy for consumption within the decentralised energy supply grid, but that it does not feed-in any electrical energy to the public supply grid.

In particular, it can be provided that the photovoltaic system can charge a battery storage integrated in the decentralised energy supply grid. Generators are thus not connected to the public electricity grid.

The application of the present monitoring system according to the invention enables the operation of large generating plants essentially independent of location, and in particular independent of feed-in regulations. In addition, the application of the monitoring system according to the invention allows at least a proportionate coverage of the own demand and thus cost savings.

### BRIEF DESCRIPTION OF THE DRAWINGS

The invention described above is explained in detail below in the light of the relevant technical background with reference to the accompanying drawings, which show preferred embodiments. The invention is not limited in any way by the purely schematic drawings, wherein it should be noted that the embodiments shown in the drawings are not limited to the dimensions shown. It is shown in

FIG. 1: a monitoring system according to the invention,

FIG. 2: representation of a power supply in an island or peninsula mode,

FIG. 3: real-time graphical display,

FIG. 4: first example of a graphical display,

FIG. 5: second example of a graphical display, and

FIG. 6: illustration of an energy balance.

### DETAILED DESCRIPTION

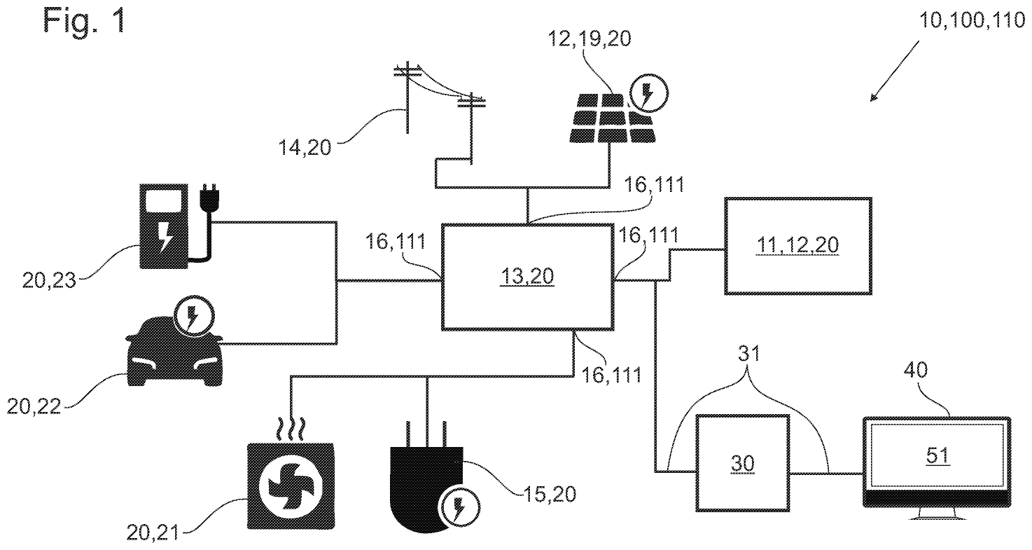

FIG. 1 schematically shows a monitoring installation 100 comprised in a monitoring system 110 according to the invention for monitoring and/or controlling at least one electrical parameter 111 in an electrical supply system 10, wherein the electrical supply system 10 comprises at least one decentralised energy supply system 12, here in the form of a photovoltaic system 19, and at least one electrochemical battery storage 11. In addition, further electrically operated and/or operable components 20 of an electrical supply system 10 are connected to the monitoring installation 100.

Said components 20 may comprise the external or public energy supply grid 14, an at least partially electrically chargeable or fully electrically operated vehicle 22 or a charging station 23 for charging such a vehicle, a heat pump 21 for generating and/or providing heat, as well as other electrically operated consumers 15 such as smart home devices or electrically operated and/or operable devices.

The measuring installation 13 of the monitoring installation 100 is configured to capture, read out and, if necessary, optimise electrical parameters 111 of the above-mentioned components 20 of the electrical supply system 10 via at least one port 16 in real time and without/with the intervention of a user. The electrical supply system 10 is configured to store unused electrical energy in the electrochemical battery storage 11 and to release it to the above-mentioned components 20 on demand.

A monitoring installation 100 for monitoring and/or controlling at least one electrical parameter 111 in an electrical supply system 10 is provided according to the invention, which, in addition to the monitoring installation 100, also comprises an internet server 30 and a user terminal 40. The internet server 30 is connected via an internet interface 31 in a monitoring system 110 to the monitoring installation 100 for transmission of the data of the electrical parameters 111 measured by the measuring installation 13 to a computer program, in particular an app 51, which can be executed on a user terminal 40 and is configured to provide a user with visualisation of the measured electrical parameters 111 of the components 20 as well as at least one possibility for controlling them.

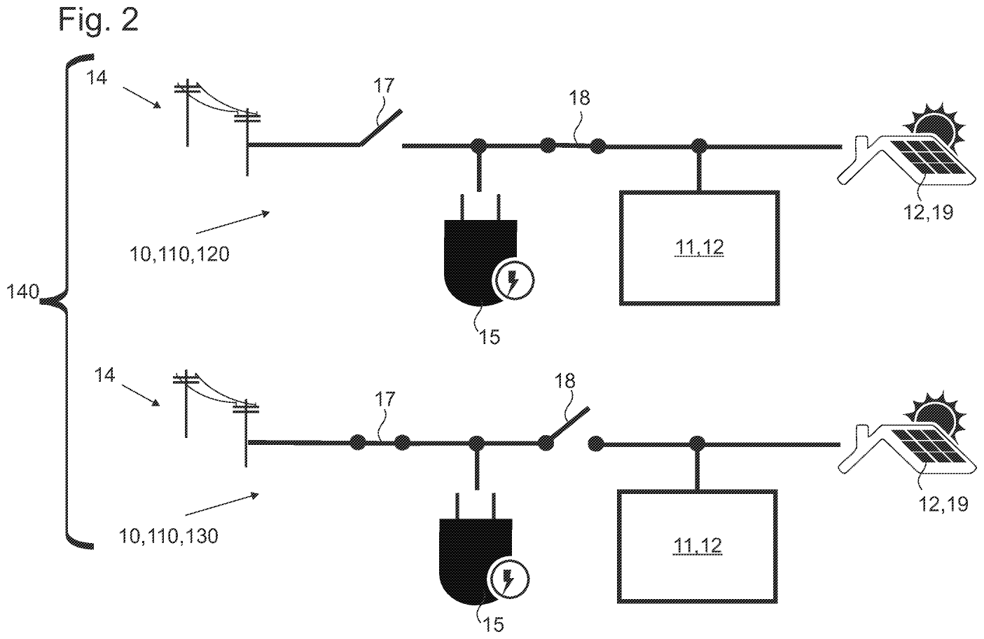

FIG. 2 schematically shows two non-limiting forms of energy supply of a monitoring system 110 for monitoring and/or controlling at least one electrical parameter 111 in an electrical supply system 10. The upper schematic shows an island operation 120, in which electrical energy for at least one consumer 15 is obtained from the electrical supply system 10, in particular from at least one decentralised energy supply system 12, in this case in the form of a photovoltaic system 19, or from at least one intermediate storage, in particular at least one electrochemical battery storage 11. Thereby, at least one grid and system protection, NA protection 17, ensures a decoupling of the electrical supply system 10, comprising decentralised energy supply system 12 and electrochemical battery storage 11, from an external energy supply grid 14, in order to prevent a grid feed-in and/or overloading of said external energy supply grid 14. Further below, a conventional grid operation 130 from an external energy supply grid 14 for the consumer(s) 15 is shown, with the addition that in this exemplary embodiment the decentralised energy supply system 12 is decoupled from the user by at least one contactor 18, so as to prevent grid feed-in of electrical energy into the external energy supply grid 14. However, this does not preclude energy generators in an electrical supply system 10, for example a photovoltaic system 19, from generating electrical energy and feeding it into the electrochemical battery storage 11 for later use.

Together, these two embodiments of a current supply form a so-called peninsula operation 140, in which it is ensured that the at least one NA protection 17 and the at least one contactor 18 are never closed at the same time, in order to accordingly prevent a grid feed-in of electrical energy from decentralised electricity generators into the public electricity grid and thus ensure a zero feed-in, so that an overload of the external energy supply grid 14 can be prevented. In this way, power consumption from the external energy supply grid 14 can be minimised and self-supply can be maximised with the help of decentralised supply systems, e.g. photovoltaic systems 19.

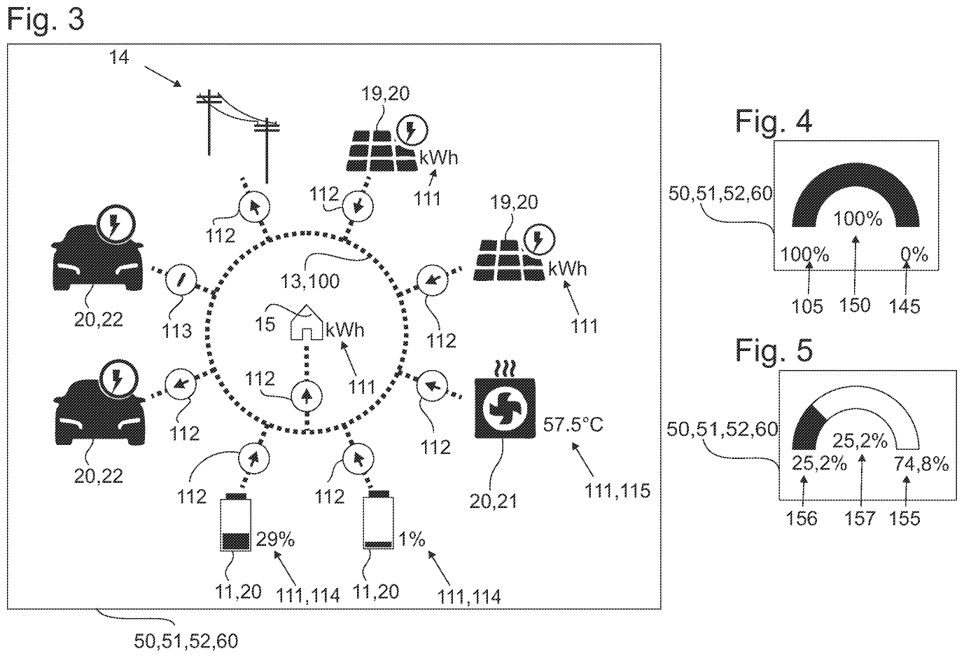

FIG. 3 shows an exemplary embodiment of a graphical display 60 implemented by initiating a computer program 50, in particular an app 51, wherein the graphical display 60 provides a user with the at least one electrical parameter 111 of at least one component 20 in an electrical supply system 10 measured by the measuring installation 13 of the monitoring installation 100 by means of an internet protocol and graphically displays said electrical parameters 111 and the associated energy flow 112 by means of a user interface 52. This provides the user with a clear, graphical display 60 of the energy flow 112 of the components 20 connected in the electrical supply system 10 in a simple manner. The components 20 connected to the measuring installation 13 of the monitoring installation 100 in the electrical supply system 10 are arranged in a circle in this display 60. Thereby, the arrows indicate the respective energy flow 112, either from the electrical supply system 10 to the components 20 connected to the measuring installation 13, as shown here, an electrically operated vehicle 22, at least one consumer 15, a heat pump 21 and also an external energy supply grid 14, according to their orientation. Temporarily non-existing energy flow 113 is indicated with a minus sign in this non-limiting exemplary embodiment. It should be noted, although not shown here, that the orientation of the arrows for at least the electrochemical battery storages 11 as well as the external energy supply grid 14 are indicated as both incoming and outgoing arrows respectively corresponding to the energy flow 112. This can mean, for example, that electrical energy can be fed-in to and/or withdrawn from the external energy supply grid 14 and/or at least one electrochemical battery storage 11 as required and an update of the graphical display 60 takes place in accordance with the energy flow control.

In addition to the energy flows 112 measured by the measuring installation 13, respective electrical parameters 111 from the components 20 connected to the measuring installation 13 and electrochemical battery storages 11 and photovoltaic systems 19 comprised in the electrical supply system 10 are displayed, such as for example the electrical power supplied, fed or discharged, as well as parameters derived therefrom, such as a charge level 114 of an electrochemical battery storage 11 or an electrically powered vehicle 22, as well as the heat 115 generated by a heat pump 21, in order to realise an easily understandable and clear graphical display 60 of the most important electrical parameters 111 of the monitoring installation 100 for a user.

The graphical display 60 described herein is additionally configured to graphically display the energy flow 112 measured by the measuring installation 13 in real time and, respectively, its electrical parameters, essentially also in real time, and to update the graphical display 60 accordingly. In addition, the respective components 20, such as the electrochemical battery storage 11 and the photovoltaic system 19, which are represented by icons in the graphical display 60, can be clicked on individually to display a more detailed representation of the electrical parameters 111.

FIG. 4 shows an exemplary embodiment of a graphical display 60, implemented by initiating a computer program 50, in particular an app 51, wherein the graphical display 60 displays, by means of an internet protocol, the at least one electrical parameter 111, measured by the measuring installation 13 of the monitoring installation 100, of at least one component 20, in particular of all components 20 integrated in the monitoring system, as described in FIGS. 1-3, in an electrical supply system 10 to a user and displays by means of a user interface 52 to which portion the measured electrical parameters from an external energy supply grid 145 and/or an electrical supply system 105 comprising at least one electrochemical battery storage 11 and at least one photovoltaic system 19 contribute to the operation of the components 20 described in FIGS. 1-3. In other words, this graphical display 60 indicates to a user the portion of self-sufficient energy supply that is provided.

FIG. 5 shows an exemplary embodiment of a graphical display 60 realized by initiating a computer program 50, in particular an app 51, wherein the graphical display 60 by means of an internet protocol provides to a user the at least one electrical parameter 111, measured by the measuring installation 13 of the monitoring installation 100, of at least one component 20, in particular of all components 20 integrated in the monitoring system, as described in FIGS. 1-3, in an electrical supply system 10 and indicates by means of a user interface 52 to what portion the stored and/or decentrally generated energy 157, and/or energy provided by the electrical supply system 10 is required for self-consumption 155, or can be fed-in 156 to the external energy supply grid 14.

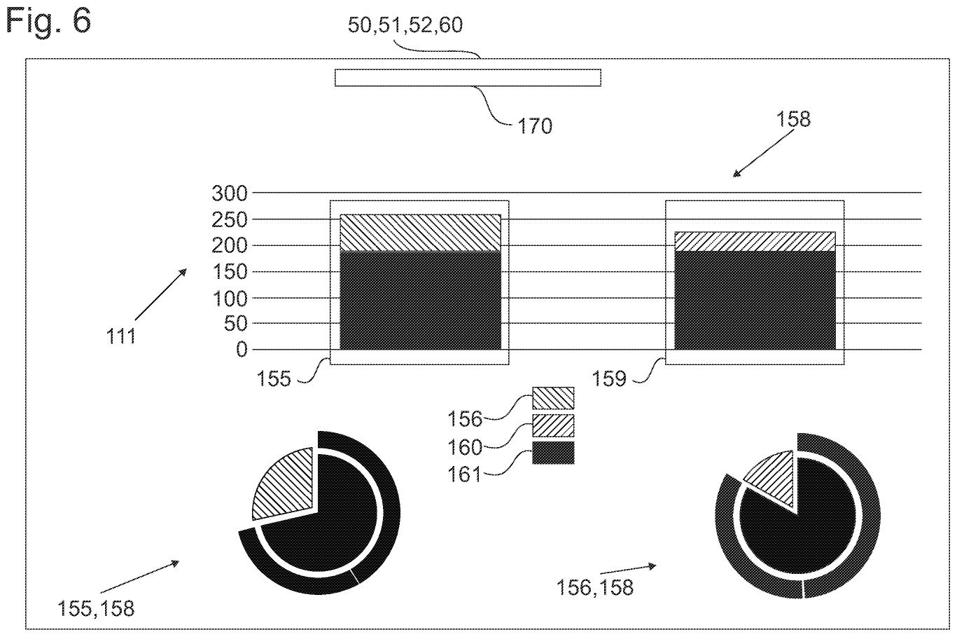

FIG. 6 shows an exemplary embodiment of a graphical display 60 realized by initiating a computer program 50, in particular an app 51, wherein the graphical display 60 provides, by means of an internet protocol, the at least one electrical parameter 111, measured by the measuring installation 13 of the monitoring installation 100, of at least one component 20, as described in FIGS. 1-3, in an electrical supply system 10 to a user and graphically displays the energy balance 158 by means of a user interface 52. Thereby, a stacked column diagram shows the energy required for self-consumption 155 or generated by an electrical supply system 10, wherein the column of self-consumption 155 is subdivided into energy from a portion of feed-in 156 from an external energy supply grid 14 as well as a portion of generated energy for self-consumption 161, and the column of generated energy 159 is subdivided into a portion of generated energy for self-consumption 161 as well as a portion of generated energy for feed-in 160 into an external energy supply grid 14. The columns thereby represent absolute energy values, for example measured in kWh. In addition, the generated energy for self-consumption 161 and generated energy 159 are also displayed in respective pie charts, as relative values in percent. Furthermore, a selection option 170 is realized for a user, with which the user can select a time period for which the energy balance is to be displayed and/or exported.

### REFERENCE NUMBERS

10 electrical supply system
11 battery storage
12 decentralised energy supply system
13 measuring installation
14 external energy supply grid
15 consumer
16 port
17 grid and system protection, NA protection
18 contactor
19 photovoltaic system
20 component
21 heat pump
22 electrically operated vehicle
23 charging station
30 internet server
31 internet interface
40 user terminal
50 computer program
51 app
52 user interface
60 graphical display
100 monitoring installation
105 portion of measured electrical parameters from an electrical supply system
110 monitoring system
111 electrical parameter
112 energy flow
113 non-existent energy flow
114 charge level
115 heat
120 island operation
130 conventional grid operation
140 peninsula operation
145 portion of measured electrical parameters from an external energy supply grid
150 portion of self-sufficient energy supply
155 self-consumption
156 feed-in
157 portion of stored and/or decentrally generated energy
158 energy balance
159 generated energy
160 generated energy for feed-in
161 generated energy for self-consumption
170 selection option

I claim:

1. Monitoring installation (100) for monitoring and/or controlling at least one electrical parameter (111) in an electrical supply system (10), comprising at least one port (16) at the electrical supply system (10) as well as a measuring installation (13) for measuring at least one electrical parameter (111) at the port (16), and comprising an internet interface (31) for transmission of at least one information relating to the electrical parameter (111) to a user terminal (40) via the internet and/or for transmission of at least one control command entered into a user terminal (40) for controlling at least one electrical parameter (111) in the electrical supply system (10) via the internet.

2. Monitoring installation according to claim 1, characterized in that the monitoring installation comprises an electrical battery storage (11) as an electrical supply system (10), wherein the measuring installation (13) is connected to a port of the battery storage (11).

3. Monitoring installation according to claim 1, characterized in that the monitoring installation comprises a photovoltaic system as an electrical supply system (10), wherein the measuring installation (13) is connected to a port (16) of the photovoltaic system.

4. Monitoring installation according to claim 1, characterized in that the monitoring installation comprises a port (16) at an external energy supply grid (14), wherein the measuring installation (13) is connected to the port (16) at the external energy supply grid (14).

5. Monitoring installation according to claim 1, characterized in that the electrical parameter (111) is:
the voltage present at the port (16)
the electric current present at the port (16)
the electrical charge present in the electrical supply system (10).

6. Monitoring system for monitoring and/or controlling at least one electrical parameter in an electrical supply system, comprising at least one monitoring installation (100) according to one of claim 1 as well as an internet server (30) and a user terminal (40), via which at least one information and/or control command relating to the electrical parameter (111) can be transmitted with a data communication via the internet between the internet interface (31) and a user terminal (40).

7. Monitoring system according to claim 6, characterized in that the monitoring system comprises a consumer and the monitoring system is configured to transmit via the internet between the internet interface (31) and the user terminal (40) at least one information relating to an electrical parameter (111) realized in the consumer and/or to transmit a control command for setting an electrical parameter (111) to be realized in the consumer.

8. Computer program, in particular an app, which can be loaded into the internal, in particular non-volatile, memory of a digital computer and which comprises a computer program code which, when executed on the digital computer, transmits via the internet protocol:
an information relating to the electrical parameter (111) determined by means of the monitoring system according to claim 6 to the user terminal (40), and/or
a control command, entered by means of the user terminal (40) of the monitoring system to the electrical supply system (10) for controlling at least one electrical parameter (111).

9. Computer program according to claim 8, characterized in that it is configured to initiate a graphical display on a user interface (52) of the user terminal (40).

10. Computer program according to claim 8, characterized in that it is configured to initiate a measurement of the electrical parameter (111).
